(19) United States
(12) Patent Application Publication
(10) Pub. No.: US 2017/0040527 A1
(43) Pub. Date: Feb. 9, 2017

(54) PIEZOELECTRIC ELEMENT, PROBE, ULTRASONIC MEASUREMENT DEVICE, ELECTRONIC APPARATUS, POLARIZATION PROCESSING METHOD, AND INITIALIZATION DEVICE

(71) Applicant: SEIKO EPSON CORPORATION, Tokyo (JP)

(72) Inventors: Hiromu MIYAZAWA, Azumino-shi (JP); Masayoshi YAMADA, Chino-shi (JP); Hiroshi ITO, Suwa-shi (JP); Tomoaki NAKAMURA, Chino-shi (JP); Hiroshi MATSUDA, Chino-shi (JP); Jiro TSURUNO, Okaya-shi (JP)

(73) Assignee: SEIKO EPSON CORPORATION, Tokyo (JP)

(21) Appl. No.: 15/227,692

(22) Filed: Aug. 3, 2016

(30) Foreign Application Priority Data
Aug. 4, 2015 (JP) 2015-153940

(51) Int. Cl. H01L 41/257; B06B 1/06

(52) U.S. Cl. CPC H01L 41/257; B06B 1/0662

(57) ABSTRACT

A piezoelectric element is provided with three electrodes, namely a first electrode, a second electrode, and a third electrode, arranged linearly on one side surface of a piezoelectric body at regular intervals. A polarization processing electric field is applied between the first electrode and the second electrode, and then the polarization processing electric field is applied between the second electrode and the third electrode. The polarization processing electrode field on this occasion is a half as strong as in the case of performing the polarization process of applying the electric field at a time between the first electrode and the third electrode.

### BACKGROUND

1. Technical Field

The present invention relates to a polarization processing method of a piezoelectric body, and so on.

2. Related Art

As an example of a piezoelectric element (an ultrasonic converter) for converting between an ultrasonic wave and an electric signal, there has been known a piezoelectric element having a so-called vertical electrode structure in which electrodes are respectively disposed on an upper surface and a lower surface of a piezoelectric body (see, e.g., JP-A-2002-271897). The principle of the piezoelectric element for generating the electric signal in response to the ultrasonic wave is that the piezoelectric body having sensed an elastic wave due to the ultrasonic wave is distorted, and thus a surface charge is generated in accordance with the distortion to generate a potential difference (a voltage) between the two electrodes.

As the structure of the piezoelectric element, besides the vertical structure described above, there has been known a so-called horizontal electrode structure in which two electrodes are disposed on one side surface of the piezoelectric body. The piezoelectric element having the horizontal electrode structure has an advantage that the reception sensitivity is high compared to the piezoelectric element having the vertical electrode structure.

Incidentally, as an initialization prior to using the piezoelectric effect, the piezoelectric element needs a polarization process of applying an electric field between the electrodes to align the direction of the polarization moment of the piezoelectric body located between the electrodes to the same direction. Although it is rare for the piezoelectric element having the vertical electrode structure to cause the problem, in the piezoelectric element having the horizontal electrode structure, the gap (distance) between the electrodes is large compared to the piezoelectric element having the vertical electrode structure. Therefore, there is a problem that the potential difference (the voltage) between the electrodes necessary for performing the polarization process becomes large.

### SUMMARY

An advantage of some aspects of the invention is to reduce the magnitude of the electric field necessary for performing the polarization process in the piezoelectric element having the horizontal electrode structure.

A first aspect of the invention is directed to a piezoelectric element in which a piezoelectric effect generated between first one of electrodes and N-th (N≧3) one of the electrodes is put into a practical use, the piezoelectric element including a piezoelectric body, and a horizontal electrode structure having N electrodes disposed on one side surface of the piezoelectric body, wherein a process, in which a polarization processing electric field in a certain direction with respect to the horizontal electrode structure is applied between i-th and former ones of the electrodes and (i+1)-th and later ones of the electrodes, is performed with respect to each of values of i=1 through (N−1) to perform a polarization process to align a polarization moment of the piezoelectric body with the certain direction.

As another aspect of the invention, the invention may be configured as a polarization processing method adapted to perform a polarization process on a piezoelectric body of a piezoelectric element, which has a horizontal electrode structure having N (N≧3) electrodes arranged on one side surface of the piezoelectric body, and in which a piezoelectric effect generated between first one of the electrodes and N^{th} one of the electrodes is put into a practical use, the method including the step of performing a process, in which a polarization processing electric field in a certain direction with respect to the horizontal electrode structure is applied between i-th and former ones of the electrodes and (i+1)-th and later ones of the electrodes, with respect to each of values of i=1 through (N−1) to perform the polarization process of aligning a polarization moment of the piezoelectric body with the certain direction.

As still another aspect of the invention, the invention may be configured as an initialization device adapted to perform a polarization process on a piezoelectric body of a piezoelectric element, which has a horizontal electrode structure having N (N≧3) electrodes arranged on one side surface of the piezoelectric body, and in which a piezoelectric effect generated between first one of the electrodes and N-th one of the electrodes is put into a practical use, the device including a unit adapted to perform a process, in which a polarization processing electric field in a certain direction with respect to the horizontal electrode structure is applied between i-th and former ones of the electrodes and (i+1)-th and later ones of the electrodes, with respect to each of values of i=1 through (N−1) to perform the polarization process of aligning a polarization moment of the piezoelectric body with the certain direction.

According to the first aspect of the invention and the like, the magnitude of the polarization processing electric field used for the polarization process of the piezoelectric body of the horizontal electrode structure can be reduced. Specifically, the piezoelectric element has the horizontal electrode structure, but is provided with N electrodes instead of two electrodes. In order to put the piezoelectric effect generated between first one of the electrodes and N-th one of the electrodes into a practical use, it is necessary to perform the polarization process between the first one of the electrodes and the N-th one of the electrodes. If it is attempted to perform the polarization process at a time between the first one of the electrodes and the N-th one of the electrodes, it is necessary to apply a strong electric field between the first one of the electrodes and the N-th one of the electrodes. However, according to the aspect of the invention, the polarization process between the first one of the electrodes and the N-th one of the electrodes can be realized by repeatedly performing the process of applying the polarization processing electric field in a certain direction to each of pairs of electrodes adjacent to each other. Therefore, since the distance between the electrodes adjacent to each other is shorter than the distance between the first one of the electrodes and the N-th one of the electrodes, the magnitude of the polarization processing electric field can be reduced.

As a second aspect of the invention, which is a more specific aspect of the invention, the piezoelectric element according to the first aspect of the invention may be configured such that a feature that a distance between electrode adjacent to each other is no smaller than 2 μm and no larger than 8 μm.

As a third aspect of the invention, the piezoelectric element according to the first or second aspects of the invention may be configured such that the polarization processing electric field is stronger than a coercive electric field of the piezoelectric body.

As a fourth aspect of the invention, which is a specific example of the horizontal electrode structure, the piezoelectric element according to any one of the first through third aspects of the invention may be configured such that the horizontal electrode structure is formed of the N electrodes arranged linearly.

As a fifth aspect of the invention, the piezoelectric element according to the fourth aspect of the invention may be configured such that the horizontal electrode structure is formed of the N electrodes arranged at regular intervals.

According to the fifth aspect of the invention, since the electrodes are arranged at the regular intervals, it is possible to uniform the polarization processing electric field applied between the electrodes.

A sixth aspect of the invention is directed to a probe including the piezoelectric element according to any one of the first through fifth aspects of the invention, and an output section adapted to output an electric signal generated between first one of the electrodes and N-th one of the electrodes, wherein the probe exerts a function as an elastic wave receiving section.

According to the sixth aspect of the invention, it is possible to realize the probe for receiving the elastic wave with the piezoelectric element having the advantage of anyone of the first through fifth aspects of the invention, and then outputting the result as an electric signal.

As a seventh aspect of the invention, the invention may be configured as an ultrasonic measurement device including the probe according to the sixth aspect of the invention adapted to receive an ultrasonic signal.

According to the seventh aspect of the invention, it is possible to realize the ultrasonic measurement device having the advantage of the sixth aspect of the invention.

As an eighth aspect of the invention, the invention may be configured as an electronic apparatus including the probe according to the sixth aspect of the invention.

According to the eighth aspect of the invention, it is possible to realize the electronic apparatus having the advantage of the sixth aspect of the invention.

### BRIEF DESCRIPTION OF THE DRAWINGS

The invention will be described with reference to the accompanying drawings, wherein like numbers reference like elements.

FIG. 1 is a diagram showing a schematic configuration of an ultrasonic measurement device according to an embodiment of the invention and an upper surface of an ultrasonic probe.

FIG. 2 is a diagram showing a lower surface of the ultrasonic probe.

FIG. 3 is a conceptual configuration diagram of an ultrasonic device unit.

FIG. 4 is a plan view of a receiving element (a piezoelectric element).

FIG. 5 is a cross-sectional view of the receiving element (the piezoelectric element).

FIGS. 6A through 6C are an explanatory diagram of a procedure of a polarization process.

FIG. 7 is a device configuration diagram when performing the polarization process.

FIG. 8 is a diagram showing another configuration example of the piezoelectric element.

FIG. 9 is a diagram showing another configuration example of the receiving element.

### DESCRIPTION OF EXEMPLARY EMBODIMENT

### 1. Ultrasonic Diagnostic Device

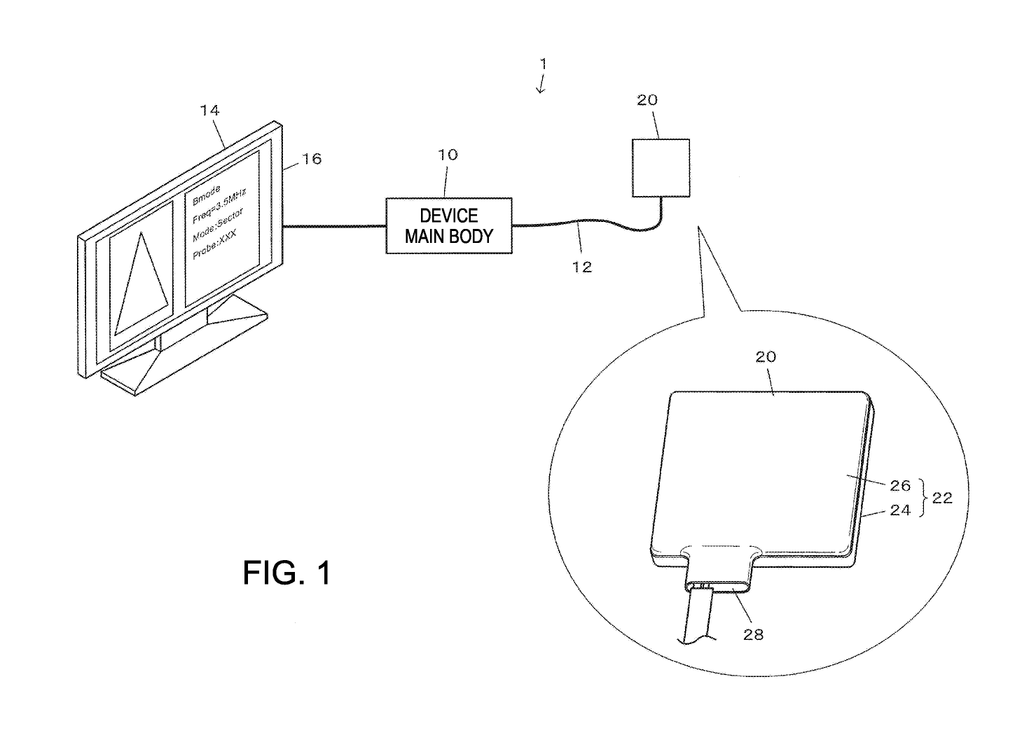

FIG. 1 is a diagram showing a schematic configuration of an ultrasonic measurement device 1 according to the present embodiment and an upper surface of an ultrasonic probe 20. According to FIG. 1, the ultrasonic measurement device 1 is an electronic apparatus for measuring living body information of a subject to be tested using an ultrasonic wave, and is configured including a device main body 10 and an ultrasonic probe 20. The device main body 10 and the ultrasonic probe 20 are connected to each other with a cable 12, a drive signal is transmitted from the device main body 10 to the ultrasonic probe 20, and at the same time, a detection signal is transmitted from the ultrasonic probe 20 to the device main body 10.

Further, a display device 14 is connected to the device main body 10. The display device 14 has a display panel 16, and displays, for example, an image based on the detection signal due to the ultrasonic probe 20 on the display panel 16 in accordance with a display signal from the device main body 10. It should be noted that the display device 14 and the device main body 10 are assumed to be separated from each other, but can also have an integrated structure.

### 2. Ultrasonic Probe

The ultrasonic probe 20 forms a housing 22 having a thin rectangular solid shape obtained by combining a obverse side body 26 and a reverse side body 24 with each other, and has an ultrasonic device unit 40 (see FIG. 3) inside the housing 22. A cable 12 is connected to the ultrasonic device unit 40 located inside the housing 22 through a cable port 28 formed between bonding surfaces of the obverse side body 26 and the reverse side body 24. The ultrasonic device unit 40 transmits the ultrasonic wave in accordance with the drive signal from the device main body 10, and at the same time, receives a reflected wave of the ultrasonic wave to output a signal of the reflected wave thus received to the device main body 10 as the detection signal.

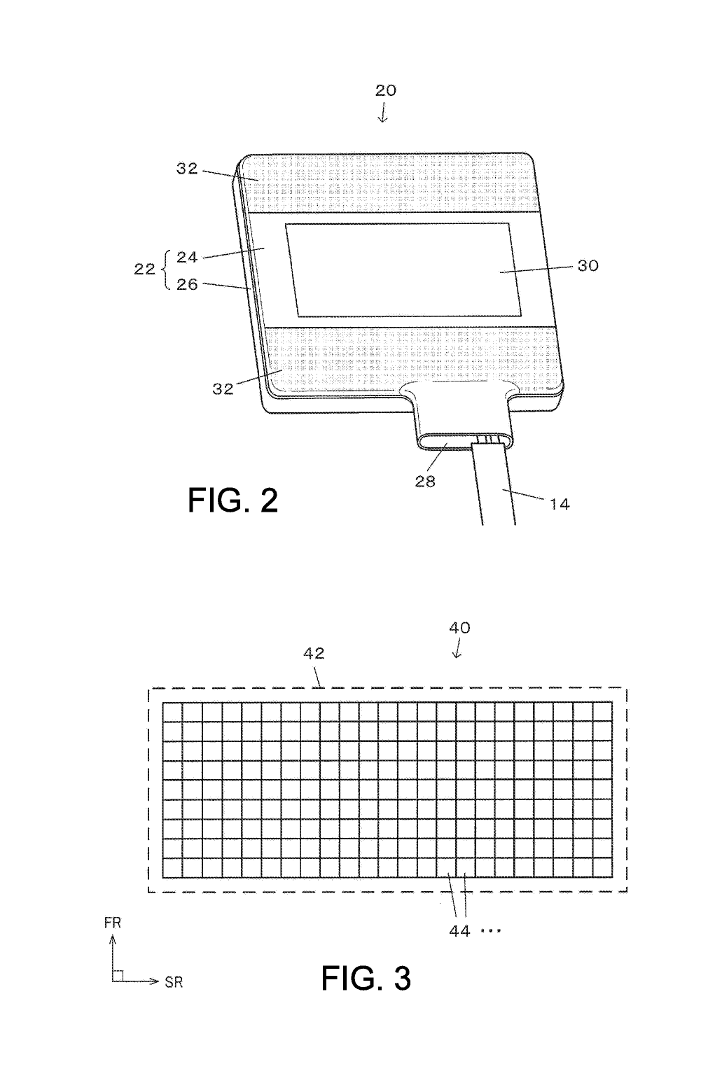

FIG. 2 is a bottom view of the ultrasonic probe 20. In the central part of the reverse side body 24, there is disposed an acoustic matching part 30, and contact parts 32 are disposed on an upper and lower parts across the acoustic matching part 30. An outer surface of the acoustic matching part 30 and outer surfaces of the contact parts 32 are formed in the state of being roughly coplanar with each other, or in the state in which the outer surface of the acoustic matching part 30 protrudes from the outer surfaces of the contact parts 32. The ultrasonic probe 20 is attached with the acoustic matching part 30 and the contact parts 32 attached firmly to a skin surface of a measurement target region of the subject to be tested. The ultrasonic device unit 40 is disposed so as to be located immediately below the acoustic matching part 30 in the housing 22. The acoustic matching part 30 is formed of a material having acoustic impedance (e.g., 1.0 through 1.5 [MRayl]) approximate to the acoustic impedance “1.5 [MRayl]” of the living body such as silicon resin. Further, the contact parts 32 are each formed of, for example, an adhesive material detachably attached to the skin surface of the measurement target region.

### 3. Ultrasonic Device Unit

FIG. 3 is a diagram conceptually showing a configuration of the ultrasonic device unit 40. The ultrasonic device unit 40 is disposed immediately below the acoustic matching part 30 viewed from the reverse surface side of the housing 22 (in FIG. 2), and is configured including an element array 42 having a plurality of ultrasonic transducers 44 arranged in a two-dimensional array. Specifically, in the element array 42, there are arranged N rows of ultrasonic transducers 44 in a first direction FR (a slicing direction), and there are arranged L columns of ultrasonic transducers 44 in a second direction SR (a scanning direction) perpendicular to the first direction FR. Each of the ultrasonic transducers 44 is configured as a transducer element chip including a transmitting element for transmitting an ultrasonic wave, and a receiving element 50 for receiving a reflected wave of the ultrasonic wave. Since the present embodiment is characterized in the receiving element 50 out of the ultrasonic transducer 44, the receiving element 50 will hereinafter be described in more detail.

### 4. Receiving Element

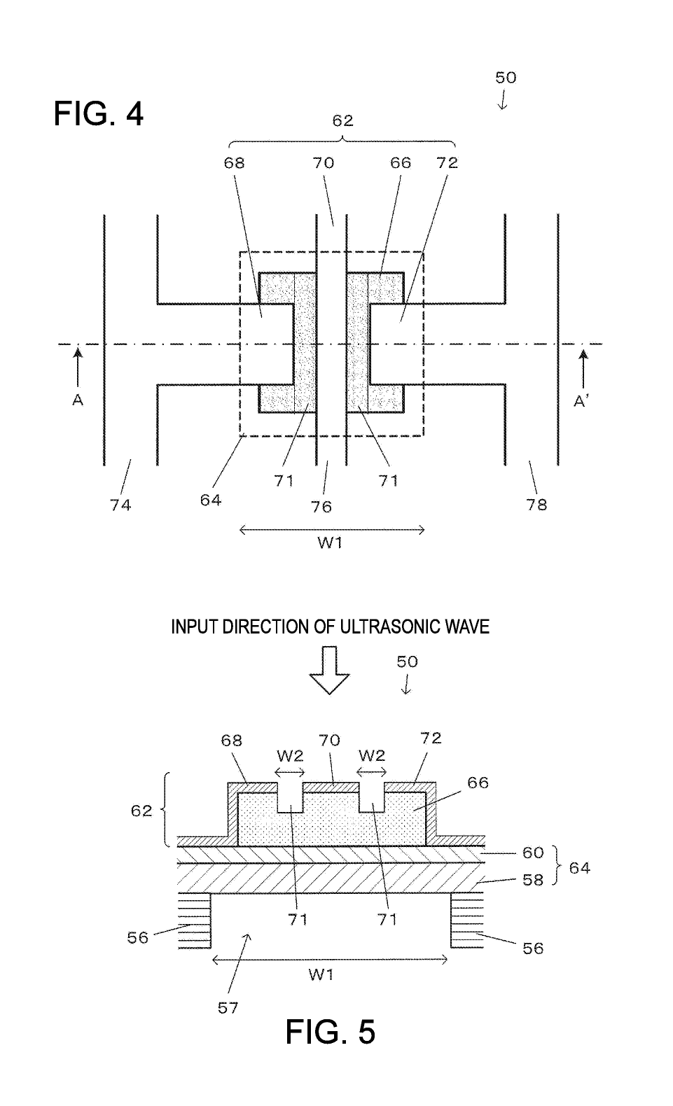

FIG. 4 is a plan view of the receiving element 50, and FIG. 5 is a cross-sectional view along the line indicated by the arrow A and the arrow A′ shown in FIG. 4. The receiving element 50 has a piezoelectric element 62 and a vibrating film 64. The piezoelectric element 62 is configured including a piezoelectric body 66, and a first electrode 68, a second electrode 70, and a third electrode 72 disposed on one side surface of the piezoelectric body 66. The piezoelectric body 66 is formed of a piezoelectric material such as lead zirconate titanate (PZT). A typical film thickness of the piezoelectric body 66 is in a range of 200 nm through 2000 nm. Further, a typical film thickness of the first electrode 68, the second electrode 70, and the third electrode 72 is in a range of 20 nm through 200 nm.

The vibrating film 64 is disposed on the opposite side to the one side surface of the piezoelectric body 66 on which the electrodes are disposed. The vibrating film 64 constitutes a flexible film having a silicon oxide (SiO₂) layer 58 and a zirconium oxide (ZrO₂) layer 60 stacked on one another. A typical film thickness of the silicon oxide layer 58 is in a range of 200 nm through 1500 nm, and a typical film thickness of the zirconium oxide 60 is in a range of 200 nm through 1500 nm.

In the present embodiment, on the opposite side to one surface of the vibrating film 64 on which the piezoelectric body 66 is disposed, there is disposed a silicon sidewall 56 so as to form a cavity (an opening part) 57. The receiving element 50 is used so that the ultrasonic wave is input from the opposite side to the cavity 57, namely the upper side in FIG. 5. The width W1 of the cavity 57 corresponds to the width W1 in an electrode arrangement direction in the receiving element 50 in a planar view (see FIG. 4). The resonant frequency of the vibrating film 64 in the electrode arrangement direction (the direction of the width W1) corresponds to the frequency f0 of the ultrasonic wave to be received. In the case in which the frequency f0 of the ultrasonic wave is in a range of 2 MHz through 20 MHz, it is desirable for the width W1 of the cavity 57 to be in a range of 15 μm through 60 μm.

The receiving element 50 is disposed with the vibrating film 64 facing to the reverse surface side of the housing 20, and vibrates when receiving an elastic wave (an ultrasonic wave in the present embodiment) via the acoustic matching part 30 (see FIG. 2).

The first electrode 68, the second electrode 70, and the third electrode 72 are formed of an electrically-conductive material such as iridium (Ir), and are disposed on one side surface (on the opposite side to the vibrating film 64) of the piezoelectric body 66 so as to be configured having the horizontal electrode structure. Specifically, the first electrode 68 is disposed on one end side of the piezoelectric body 66, the third electrode 72 is disposed on the other end side of the piezoelectric body 66, and second electrode 70 is disposed between the first electrode 68 and the third electrode 72. Further, the first electrode 68, the second electrode 70, and the third electrode 72 are disposed so as to have intervals W2 equal to each other. The intervals W2 between the electrodes is set to be no smaller than 2 μm and no larger than 8 μm. In other words, the first electrode 68, the second electrode 70, and the third electrode 72 are arranged linearly at regular intervals. Further, on parts of the surface of the piezoelectric body 66 located between the first electrode 68 and the second electrode 70 and between the second electrode 70 and the third electrode 72, there are formed grooves 71 in a direction crossing the linear arrangement of the three electrodes. Further, the first electrode 68 is connected to a first electrode line 74, the second electrode line 70 is connected to a second electrode line 76, and the third electrode 72 is connected to a third electrode line 78.

Although in the present embodiment, the illustration and the explanation are presented assuming that each of the receiving elements 50 is configured including one piezoelectric element 62 for the sake of simplification of the explanation, it is also possible to assume that each of the receiving elements 50 is configured including two or more piezoelectric elements 62. In this case, it is sufficient for the two or more piezoelectric elements 62 included in each of the receiving elements 50 to be connected in parallel to each other. Specifically, each of the receiving elements 50 can be configured by connecting the first electrode 68, the second electrode 70, and the third electrode 72 of each of the piezoelectric elements 62 to the first electrode line 74, the second electrode line 76, and the third electrode line 78 corresponding respectively thereto.

### 5. Receiving Process

In the receiving process of the ultrasonic wave by the piezoelectric element 62, a signal of the potential difference (i.e., an electric signal) corresponding to the ultrasonic wave received appears between the first electrode line 74 (which can also be reworded as the first electrode 68) and the third electrode line 78 (which can also be reworded as the third electrode 72), and is then output as the detection signal. More specifically, the ultrasonic wave having been transmitted from the transmitting element of the ultrasonic transducer 44 is reflected inside the living body of the subject to be tested, and the vibrating film 64 senses the reflected wave (the elastic wave), and then vibrates. Since the vibrating film 64 and the piezoelectric body 66 are integrally configured, the piezoelectric body 66 is distorted in response to the deformation of the vibrating film 64 due to the ultrasonic vibration. In the piezoelectric body 66, the surface charge corresponding to the distortion is generated, and a potential difference (voltage) appears between the first electrode 68 and the third electrode 72, and is then taken out as the detection signal due to the piezoelectric effect generated between the first electrode 68 and the third electrode 72. Since the detection signals of the respective piezoelectric elements 62 are detected for each of the ultrasonic transducers 44, the detection signal is obtained for each cell of the dot matrix shown in FIG. 3.

### 6. Polarization Process

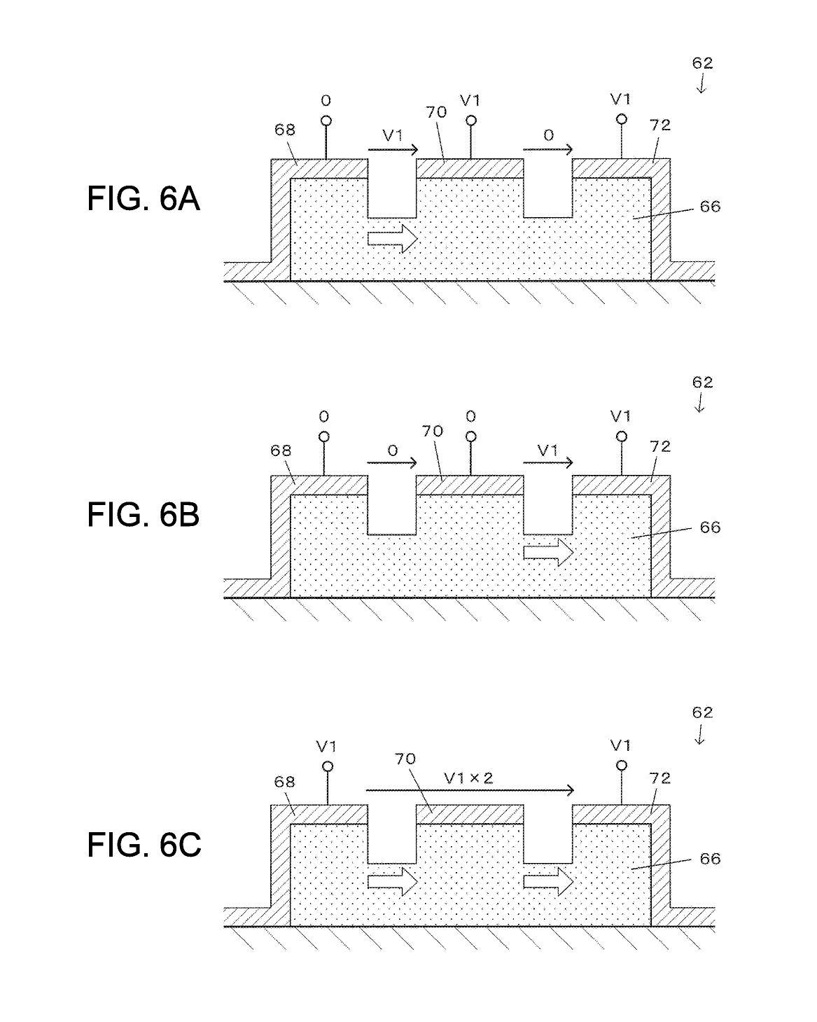

The polarization process for aligning the directions of the polarization moments of the respective piezoelectric bodies 66 needs to be performed on the piezoelectric elements 62 as an initialization process for obtaining the desired piezoelectric effect. FIGS. 6A through 6C are explanatory diagrams of the procedure of the polarization process to the piezoelectric element 62. The polarization process is performed in a plurality of steps. Specifically, a polarization processing electric field, which is a predetermined direct-current electric field, is applied sequentially to the pairs of electrodes adjacent to each other targeting at the piezoelectric body parts between the electrodes. In the present embodiment, since the piezoelectric element 62 has the three electrodes (the first electrode 68, the second electrode 70, and the third electrode 72) arranged linearly, and the number of the pairs of electrodes adjacent to each other is two, the polarization process is performed in two steps. Further, the polarization processing electric field to be applied has a direction from the first electrode 68 toward the third electrode 72 used for the detection in the receiving process, and since the intervals W2 between the electrodes adjacent to each other are the same, the magnitude of the polarization processing electric field used in the polarization process is the same between the two steps.

Specifically, as shown in FIG. 6A, the polarization processing electric field V1 from the first electrode 68 toward the second electrode 70 is firstly applied between the first electrode 68 and the second electrode 70. In other words, the potential of the first electrode 68, namely the first one of the electrodes, is set to “0,” and the potentials of the second electrode 70 and the third electrode 72, namely the second and later ones of the electrodes, are set to the same potential of “V1.” Thus, the part of the piezoelectric body 66 located between the first electrode 68 and the second electrode 70 is polarized in the direction from the first electrode 68 toward the second electrode 70.

Subsequently, as shown in FIG. 6B, the polarization processing electric field V1 from the second electrode 70 toward the third electrode 72 is applied between the second electrode 70 and the third electrode 72. In other words, the potentials of the first electrode 68 and the second electrode 70, namely the second and former ones of the electrodes, are set to the same potential of “0,” and the potential of the third electrode 72, namely the third one of the electrodes, is set to “V1.” Thus, the part of the piezoelectric body 66 located between the second electrode 70 and the third electrode 72 is polarized in the direction from the second electrode 70 toward the third electrode 72.

Thus, as shown in FIG. 6C, there can be obtained the effect of the polarization process substantially the same as the case of applying the polarization processing electric field V1×2 between the first electrode 68 and the third electrode 72. In other words, in the present embodiment, the magnitude of the polarization processing electric field can be reduced compared to the case of performing the polarization process at a time on the part between the first electrode 68 and the third electrode 72 used in the receiving process. A typical value of the polarization processing electric field V1 is in a range of 20 V through 60 V. The magnitude of the polarization processing electric field V1 needs to be made greater than the coercive electric field Vc as the electric field with which the polarization inversion occurs in the piezoelectric body 66.

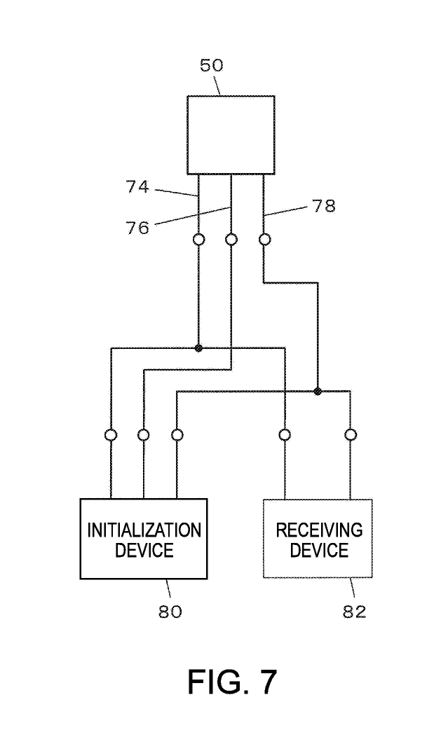

The actual polarization process is performed by an initialization device 80. FIG. 7 shows a conceptual diagram showing a connection relationship between the receiving element 50 and the initialization device 80. Although FIG. 7 shows the single receiving element 50 alone for the sake of simplification of the explanation, in reality, the receiving elements 50 of the respective ultrasonic transducers 44 constituting the ultrasonic device unit 40 are similarly connected to the device main body 10.

The device main body 10 is provided with the initialization device 80 for performing the polarization process for the initialization, and a receiving device 82 for performing the receiving process related to the reception of the ultrasonic wave. Although the illustration and the explanation will be omitted, it is obvious that the device main body 10 is also provided with a device for performing the transmitting process related to the transmission of the ultrasonic wave, a display control device for performing the display control of the display device 14, and so on. The electrode lines (the first electrode line 74, the second electrode line 76, and the third electrode line 78) of the receiving element 50 are connected to the initialization device 80 and the receiving device 82, and are used in a switched manner so that the initialization device 80 applies the voltage to the electrode lines when performing the initialization (the polarization process), or the receiving device 82 obtains the potentials appearing in the electrode lines (more specifically, the potentials of the first electrode line 74 and the third electrode line 78) when performing the receiving process.

The initialization device 80 applies the predetermined potentials to the respective electrode lines to thereby apply the polarizing electric field between the electrodes to perform the polarization process. Specifically, by setting the potential of the first electrode line to “0 (GND),” and setting the potentials of the second electrode line 76 and the third electrode line 78 to “V1,” the polarization processing electric field V1 is applied between the first electrode line 74 and the second electrode line 76. Subsequently, by setting the potentials of the first electrode line 74 and the second electrode line 76 to “0 (GND),” and setting the potential of the third electrode line 78 to “V1,” the polarization processing electric field V1 is applied between the second electrode line 76 and the third electrode line 78.

### Functions and Advantages

As described above, according to the present embodiment, in the piezoelectric element 62 having the horizontal electrode structure, the polarization processing electric field can be reduced. Specifically, the piezoelectric element 62 is provided with the three electrodes, namely the first electrode 68, the second electrode 70, and the third electrode 72, arranged linearly on one side surface of the piezoelectric body 66 at regular intervals. In the case of receiving the ultrasonic wave using the piezoelectric effect, the potential difference (the voltage) between the first electrode 68 and the third electrode 72 can be taken out as the detection signal of the ultrasonic wave. The polarization process to the piezoelectric body 66 as the initialization for using the piezoelectric effect is performed by applying the polarization processing electric field in the predetermined same direction in sequence to the pairs of the electrodes adjacent to each other. In other words, firstly, the polarization processing electric field V1 is applied between the first electrode 68 and the second electrode 70, and then the polarization processing electric field V1 is applied between the second electrode 70 and the third electrode 72. The polarization processing electrode field V1 on this occasion is a half as strong as in the case of performing the polarization process of applying the electric field at a time between the first electrode 68 and the third electrode 72.

### Modified Examples

It should be noted that it is obvious that the applicable embodiment of the invention is not limited to the embodiment described above, but can arbitrarily be modified within the scope or the spirit of the invention.

### A. Number N of Electrodes

Although in the embodiment described above, there is described the piezoelectric element 62 having the three (N=3) electrodes, namely the first electrode 68, the second electrode 70, and the third electrode 72, arranged, the invention can similarly be applied to a piezoelectric element having four or more (N>3) electrodes arranged.

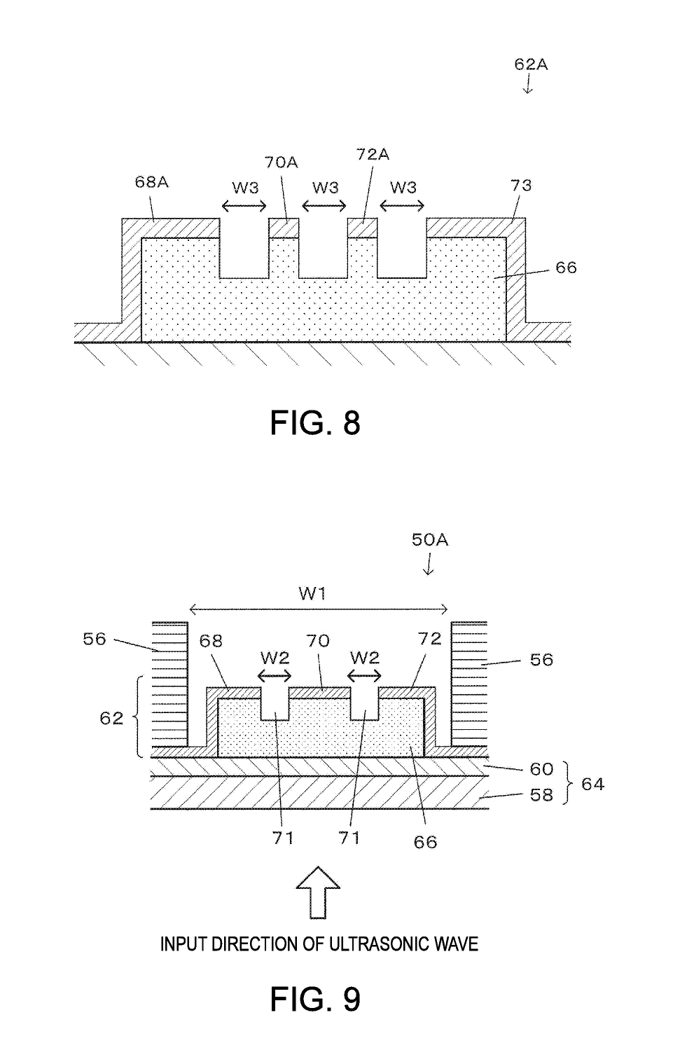

FIG. 8 is a cross-sectional view of a piezoelectric element 62A having the four electrodes (N=4). As shown in FIG. 8, the piezoelectric element 62A has four electrodes, namely a first electrode 68A, a second electrode 70A, a third electrode 72A, and a fourth electrode 73, arranged on one side surface of the piezoelectric body 66. The first electrode 68A, the second electrode 70A, the third electrode 72A, and the fourth electrode 73 are linearly arranged so that the intervals W3 between the electrodes adjacent to each other are equal to each other. By making the sum (W3×3) of the intervals W3 between the electrodes equal to the sum (W2×2) of the intervals W2 between the electrodes of the piezoelectric element 62 in the embodiment described above, the piezoelectric element 62A can achieve the reception sensitivity equivalent to that of the piezoelectric element 62.

In the polarization process to the piezoelectric element 62A, it is sufficient to apply the polarizing electric field V4 equal in magnitude in the same direction in sequence to the pairs of electrodes adjacent to each other. In other words, the potential of the first electrode 68A, namely the first one of the electrodes, is set to “0 (GND),” and the potentials of the second electrode 70A, the third electrode 72A, and the fourth electrode 73, namely the second and later ones of the electrodes, are set to the same potential of “V4.” Subsequently, the potentials of the first electrode 68A and the second electrode 70A, namely the second and former ones of the electrodes, are set to “0 (GND),” and the potentials of the third electrode 72A and the fourth electrode 73, namely the third and later ones of the electrodes, are set to the same potential of “V4.” Subsequently, the potentials of the first electrode 68A, the second electrode 70A, and the third electrode 72A, namely the third and former ones of the electrodes, are set to “0 (GND),” and the potential of the fourth electrode 73, namely the fourth one of the electrodes, is set to the same potential of “V4.”

Further, the same also applies to a piezoelectric element having five or more (N≧5) electrodes. Specifically, the N (N≧5) electrodes are arranged linearly on one side surface of the piezoelectric body at regular intervals. Further, as the polarization process to the piezoelectric element, a process of applying the predetermined polarizing electric field between the i-th and former ones of the electrodes and the (i+1)-th and later ones of the electrodes is performed in sequence with respect to each of the values of i=1 through (N−1).

### B. Shape

Further, although in the embodiment described above, it is assumed that the planar shape (the shape shown in FIG. 4) of the piezoelectric element 62 is the square shape, there can also be adopted other rectangular shapes such as a rectangular shape, or other shapes such as a polygonal shape or an elliptical shape.

### C. Intervals Between Electrodes

Further, although in the embodiment described above, it is assumed that the intervals between the electrodes adjacent to each other are equal to each other, it is also possible to assume that the intervals are different from each other. In this case, assuming that, for example, the number N of the electrodes is three, the interval between the first electrode and the second electrode is W11, and the interval between the second electrode and the third electrode is W12, by setting the magnitude of the polarizing electric field to be applied between the second electrode and the third electrode to be (W12/W11) times as great as the magnitude of the polarizing electric field to be applied between the first electrode and the second electrode, it is possible to homogenize the polarization moment between the electrodes. In other words, it is preferable to assume that the length of the interval between the electrodes adjacent to each other and the magnitude of the polarizing electric field are made proportional to each other.

### D. Input Direction of Ultrasonic Wave

Further, it is also possible to adopt the configuration in which the input direction of the ultrasonic wave to the receiving element 50 is different. Specifically, it is possible to configure a receiving element 50A having the silicon sidewalls 56 disposed on the same arrangement surface side as that of the piezoelectric element 62 with respect to the vibrating film 64 so as to sandwich the piezoelectric element 62 as shown in FIG. 9. The receiving element 50A is used so that the ultrasonic wave is input from the lower side in FIG. 9.

The entire disclosure of Japanese Patent Application No. 2015-153940 filed on Aug. 4, 2015 is expressly incorporated by reference herein.

What is claimed is:

1. A piezoelectric element in which a piezoelectric effect generated between first one of electrodes and N-th (N≧3) one of the electrodes is put into a practical use, the piezoelectric element comprising:
a piezoelectric body; and
an electrode structure having N electrodes disposed on one side surface of the piezoelectric body,
wherein a process, in which a polarization processing electric field in a certain direction with respect to the electrode structure is applied between i-th and former ones of the electrodes and (i+1)-th and later ones of the electrodes, is performed with respect to each of values of i=1 through (N−1) to perform a polarization process to align a polarization moment of the piezoelectric body with the certain direction.

2. The piezoelectric element according to claim 1, wherein
a distance between electrode adjacent to each other is no smaller than 2 μm and no larger than 8 μm.

3. The piezoelectric element according to claim 1, wherein
the polarization processing electric field is stronger than a coercive electric field of the piezoelectric body.

4. The piezoelectric element according to claim 1, wherein
the electrode structure is formed of the N electrodes arranged linearly.

5. The piezoelectric element according to claim 4, wherein
the electrode structure is formed of the N electrodes arranged at regular intervals.

6. A probe comprising:
the piezoelectric element according to claim 1; and
an output section adapted to output an electric signal generated between first one of the electrodes and N-th one of the electrodes,
wherein the probe exerts a function as an elastic wave receiving section.

7. A probe comprising:
the piezoelectric element according to claim 2; and
an output section adapted to output an electric signal generated between first one of the electrodes and N-th one of the electrodes,
wherein the probe exerts a function as an elastic wave receiving section.

8. A probe comprising:
the piezoelectric element according to claim 3; and
an output section adapted to output an electric signal generated between first one of the electrodes and N-th one of the electrodes,
wherein the probe exerts a function as an elastic wave receiving section.

9. A probe comprising:
the piezoelectric element according to claim 4; and
an output section adapted to output an electric signal generated between first one of the electrodes and N-th one of the electrodes,
wherein the probe exerts a function as an elastic wave receiving section.

10. A probe comprising:
the piezoelectric element according to claim 5; and
an output section adapted to output an electric signal generated between first one of the electrodes and N-th one of the electrodes,
wherein the probe exerts a function as an elastic wave receiving section.

11. An ultrasonic measurement device comprising:
the probe according to claim 6 adapted to receive an ultrasonic signal.

12. An ultrasonic measurement device comprising:
the probe according to claim 7 adapted to receive an ultrasonic signal.

13. An ultrasonic measurement device comprising:
the probe according to claim 8 adapted to receive an ultrasonic signal.

14. An ultrasonic measurement device comprising:
the probe according to claim 9 adapted to receive an ultrasonic signal.

15. An electronic apparatus comprising:
the probe according to claim 6.

16. An electronic apparatus comprising:
the probe according to claim 7.

17. An electronic apparatus comprising:
the probe according to claim 8.

18. An electronic apparatus comprising:
the probe according to claim 9.

19. A polarization processing method adapted to perform a polarization process on a piezoelectric body of a piezoelectric element, which has an electrode structure having N (N≧3) electrodes arranged on one side surface of the piezoelectric body, and in which a piezoelectric effect generated between first one of the electrodes and N-th one of the electrodes is put into a practical use, the method comprising:
performing a process, in which a polarization processing electric field in a certain direction with respect to the electrode structure is applied between i-th and former ones of the electrodes and (i+1)-th and later ones of the electrodes, with respect to each of values of i=1 through (N−1) to perform the polarization process of aligning a polarization moment of the piezoelectric body with the certain direction.

20. An initialization device adapted to perform a polarization process on a piezoelectric body of a piezoelectric element, which has an electrode structure having N (N≧3) electrodes arranged on one side surface of the piezoelectric body, and in which a piezoelectric effect generated between first one of the electrodes and N-th one of the electrodes is put into a practical use, the device comprising:
a unit adapted to perform a process, in which a polarization processing electric field in a certain direction with respect to the electrode structure is applied between i-th and former ones of the electrodes and (i+1)-th and later ones of the electrodes, with respect to each of values of i=1 through (N−1) to perform the polarization process of aligning a polarization moment of the piezoelectric body with the certain direction.
